(19) United States
(12) Patent Application Publication
(10) Pub. No.: US 2019/0018323 A1
(43) Pub. Date: Jan. 17, 2019

(54) HOROLOGICAL COMPONENT FORMED FROM AMAGNETIC BINARY CuNi ALLOY

(71) Applicant: Société anonyme de la Manufacture d'horlogerie Audemars Piguet & Cie, Le Brassus (CH)

(72) Inventors: Sandra GUADALUPE-MALDONADO, Apples (CH); Tiavina NIARITSIRY, Le Sentier (CH); Laeticia PHILIPPE, Berne (CH); Cédric FRANTZ, Steffisburg (CH)

(21) Appl. No.: 16/029,974

(22) Filed: Jul. 9, 2018

(30) Foreign Application Priority Data
Jul. 12, 2017 (CH) 00906/17

(51) Int. Cl. G03F 7/40; G04B 15/14; G04B 17/06; C22C 9/06; C25D 3/66

(52) U.S. Cl. CPC G03F 7/40; G04B 15/14; C25D 3/44; C22C 9/06; C25D 3/665; G04B 17/063

(57) ABSTRACT

A monolithic horological component comprising a binary amagnetic CuNi alloy, said component being obtained by a process comprising the production of a mold for said component by photolithography and a step for electrodeposition. The fabrication process for the monolithic horological component is selected from UV-LiGA type processes.

### RELATED APPLICATION

The present application claims priority to Swiss Patent Application No. 00906/17, filed Jul. 12, 2017, the disclosure of which is hereby incorporated by reference herein in its entirety.

### FIELD OF THE INVENTION

The present invention relates to a monolithic horological component.

The term “monolithic horological component” as used in the present invention means a component formed from a single piece for incorporation into timepieces such as wristwatches and chronometers. This type of component is used in particular in the field of mechanical wristwatches.

### BACKGROUND OF THE INVENTION

In order to obtain optimal performances of key parts for chronometry such as balance springs, balance wheels or escape wheels, it is important to avoid the effects of magnetism as far as possible. A very partial solution could consist of using magnetic shielding with the aid of materials which attract magnetic field lines and deflect them away from sensitive components.

Another current solution is to use silicon, in particular for the balance spring. This material, which performs well in this application, was not used in the traditional horological art. However, the use of this material is not without its problems: because it is anisotropic, it could exhibit variations in the Young's modulus as a function of the crystal direction. Another problem resides in its brittle behaviour linked to its great hardness.

Other horological components have, for example, been produced from Elinvar, from other ternary alloys, for example FeNiCr, or from other non-magnetic ferreous materials such as FeCrNiMnBe alloys as proposed in document CH 711 913.

Thereby, the document GB 1 156 574 proposes the fabrication of watch springs with a low thermal coefficient using a non-magnetic alloy based on FeNiCr, with additional minor components. That document does not disclose the method by which that alloy is fabricated, nor the method for forming such a spring. That document therefore does not propose a solution to the production of very small horological components.

The document EP 2 487 547, which concerns a regulator for horological wheels incorporating several components made from different materials, mentions a spring formed from a non-magnetic FeNiCr type material for which the elastic modulus varies only slightly as a function of temperature, which can be produced using a LiGA (Lithographie, Galvanoformung, Abformung [Lithography, Electroplating and Moulding]) technique.

The document US 2004/0154925 describes the fabrication of MEMS (micro-electro-mechanical systems) by the electrolytic deposition of composite materials constituted by alloys filled with nanoparticles, in particular NiCu alloys, with Ni being in the majority, filled with alumina, in hollow structures with depths in the range 10 to 2000 microns. Those hollow structures are produced by means of an X-LiGA process.

Several documents of the prior art propose the use of nickel-phosphorus (NiP) binary alloys for producing watch components. However the document CH 705 680 mentions that LiGA technology is employed in the horological field for the fabrication of nickel-phosphorus alloys, but can result in parts with wear resistance defects. It describes a process for the improvement of the hardness of certain specific zones of a component produced from a NiP12 alloy, employing an annealing step.

Many documents of the prior art have as their object surface treatments of parts formed from metal, ceramic or plastic, by depositing thin layers of CuNi of the order of tens of microns. These treatments are intended to increase the corrosion resistance of those parts or have a decorative purpose. For example, the European patent EP 2 840 169 describes a galvanization bath solution containing six components, comprising salts of Ni and of Cu as well as additives for densification of the layers; that bath solution has excellent chemical stability, which means that the costs of the industrial galvanization process can be reduced.

The document EP 3 098 670 describes components for internal casing of watches, for example ornaments or indexes, obtained by mechanical machining of an alloy based on, by the majority, copper, on nickel and on another component such as Mn, Al, Zr, present in small proportions.

In the documents CH 712 718, CH 712 719, CH 712 760 and CH 712 762, all published on Jan. 31, 2018, the applicant proposes to produce a pivot axis of a watch component by mechanical machining of a amagnetic alloy chosen from austenitic alloys, copper alloys such as bronzes, cupronickels, CuBe, etc., and to harden the surface of the axis either by a galvanic deposition of NiB or NiP or by diffusion of heteroatoms, for example boron, from the surface of the axis to a specific depth. Because of the hardening step, these components have heterogeneous structures.

### SUMMARY OF THE INVENTION

An objective of the present invention is to overcome the disadvantages of the horological components and fabrication methods of the prior art, and in particular to enable the production of monolithic non-magnetic horological components with a wide freedom in design of the forms.

Another objective is the production of such components that are homogeneous and isotropic.

Another aim is the production of components with a high Young's modulus, in particular a Young's modulus with a low thermal variation.

To this end, in a first aspect, the present invention proposes a monolithic horological component comprising a binary amagnetic CuNi alloy, said component being obtained by a process comprising the production of a mold for said component by photolithography and a step for electrodeposition.

These measures allow that the user is provided with non-magnetic parts produced from a homogeneous and isotropic material with a uniform crystalline structure. The amagnetic binary CuNi alloys, these alloys comprising in their structure only Cu and Ni elements and any technically unavoidable impurities, have excellent fatigue resistance, as well as resistance to corrosion caused by salt water, for example.

In addition, the user is provided with parts for which the Young's modulus is not affected by the crystallite direction.

The production of molds which have a hollowed shape which is complementary to that of the horological components by means of photolithography provides for great freedom in the design as regards the two-dimensional form of these horological components.

In a second aspect, the present invention provides monolithic horological components of the type mentioned above, obtained by a process selected from UV-LiGA type processes. This type of process offers substantial safety as regards carrying it out and requires far less outlay as regards technological material than in other photolithographic processes, for example X-LiGA technology.

The process selected in the context of the invention offers great latitude as regards varying the electrochemical parameters for electrodeposition in order to improve the properties of the material during its growth, in particular to obtain a uniform crystalline structure.

By these measures, the user can therefore have amagnetic horological components which are homogeneous, that is to say whose properties are uniform throughout the material, and isotropic, that is to say whose mechanical properties are identical in all directions.

Other characteristics as well as the corresponding advantages will become apparent from the dependent claims and from the more detailed description of the invention below.

### BRIEF DESCRIPTION OF THE DRAWINGS

The accompanying drawings represent embodiments of the invention, by way of examples.

FIG. 1 shows microphotographs of CuNi alloys of the prior art.

FIG. 2 shows a microphotograph of a section of a CuNi alloy in accordance with the invention.

FIG. 3 shows a diffractogram of the alloy of FIG. 2.

FIG. 4 shows an escape wheel in accordance with the invention.

FIG. 5 shows a balance spring in accordance with the invention.

FIG. 6 is a table summarizing the operating conditions for the step for electrodeposition of two CuNi alloys in accordance with the invention.

FIG. 7 is a table summarizing variations of the composition of the electrodeposition solution baths in accordance with the invention.

### DETAILED DESCRIPTION OF THE INVENTION

The invention will now be described in detail with reference to the accompanying figures which illustrate several embodiments of the invention by way of example.

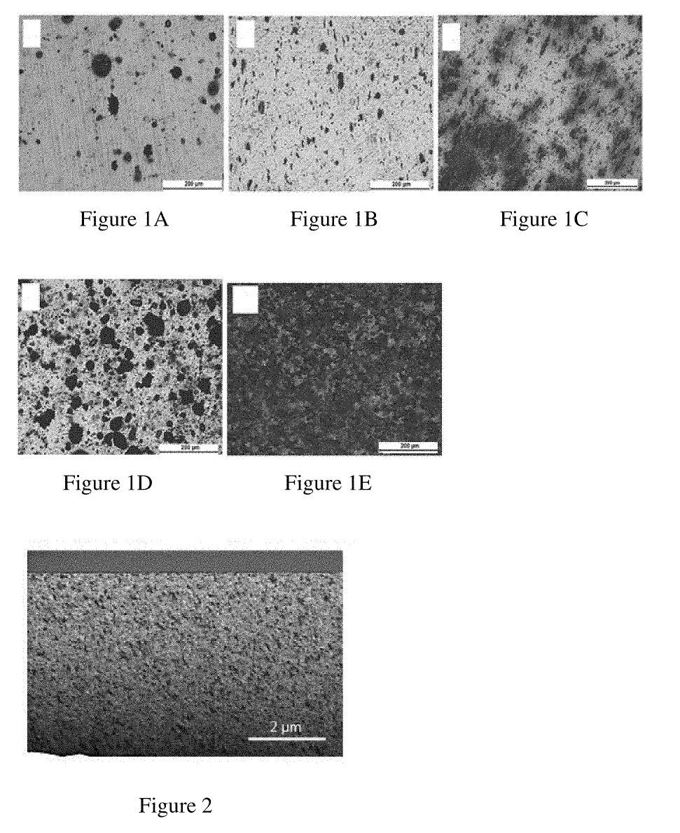

FIG. 1 reproduces microphotographs of five CuNi alloys prepared using a standard metallurgical process, powder compression, followed by sintering in a vacuum furnace. The five alloys were produced by this method with the following compositions: Ni-5% by wt Cu, Ni-10% by wt Cu, Ni-20% by wt Cu, Ni-30% by wt Cu and Ni-50% by wt Cu. The microphotographs shown in FIG. 1 are extracted from the article “Metallurgically prepared NiCu alloys as cathode materials for hydrogen evolution reaction” by Kunchan Wang and Ming Xia, Materials Chemistry and Physics 186 (2017), pages 61 to 66. They exhibit a heterogeneity in their microstructures, with two phases coexisting in distinct domains.

FIG. 2 shows a microphotograph of a section of a CuNi alloy produced by ionic milling and ion microscopy of a section of a part obtained by electrodeposition using a LiGA process, in accordance with the invention. In FIG. 2, a microstructure of the alloy is observed which is characterized by a uniform distribution of nanocrystalline grains.

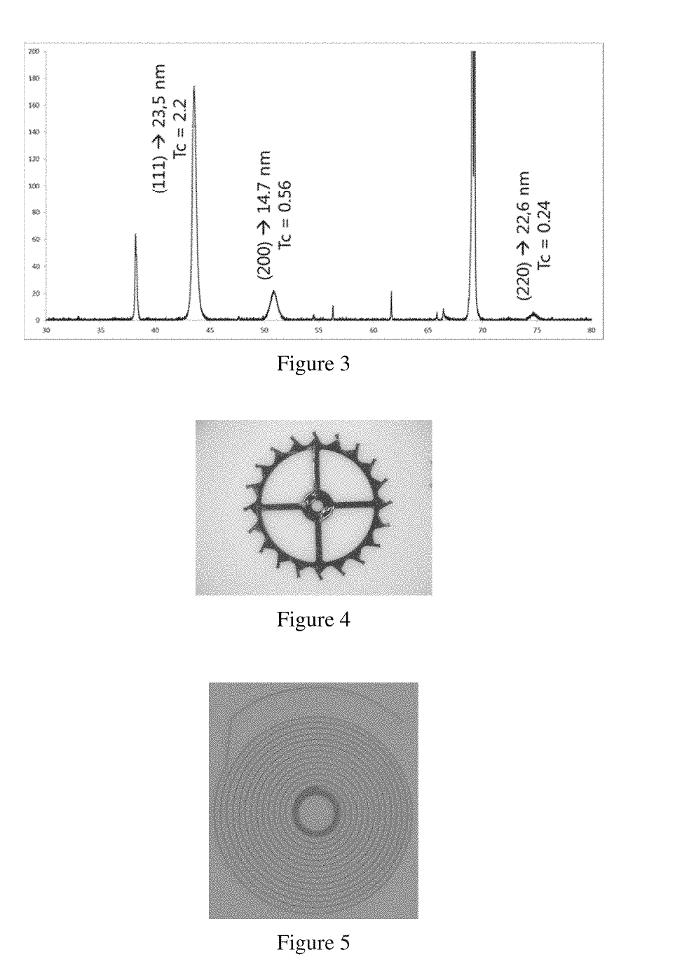

The alloy shown in FIG. 2 was analyzed by X ray diffractometry (XRD). The XRD diffractogram is shown in FIG. 3; the grain size was evaluated using the Scherrer equation, along with the texture coefficients associated with each crystallographic plane. This diffractogram exhibits a large peak in the (111) orientation, which indicates the formation of textured deposits, with texture along the {111} plane. Such a peak is not visible in the diffractograms of alloys obtained using a standard metallurgical process such as that given above.

It thus follows that a binary CuNi alloy obtained by an electrodeposition process in accordance with the invention has a metallurgical microstructure which differs from that of a CuNi alloy comprising the components Cu and Ni in the same proportions, but obtained by a standard metallurgical process.

As a result, a monolithic horological component constituted by or comprising a binary amagnetic CuNi alloy obtained by an electrodeposition process has a metallurgical structure which is different from that which would have a horological component with the same shape and produced by a standard metallurgical process.

The person skilled in the art is aware that the components Cu and Ni are miscible in all proportions in order to form binary alloys, with the magnetic properties of the alloys being a function of these proportions. These alloys have ferromagnetic type properties when the proportion of Ni is more than approximately 60% by weight.

In the broadest sense of the present invention, the monolithic components constituted by a binary CuNi alloy obtained by electrodeposition are those which are amagnetic because of the proportions of the components Cu and Ni.

In particular, the monolithic horological components according to the invention are constituted by a binary alloy Cu(x) Ni(100-x), in which 45<x<80, where x designates the atomic percentage of copper. More specifically, the monolithic horological components according to the invention are constituted by a binary alloy Cu(x) Ni(100-x), in which 55<x<75. In particular, if x is approximately 55, in which x designates the atomic percentage of copper, the alloy exhibits a minimum thermal variation in mechanical properties at the usual ambient temperatures.

The monolithic horological components according to the invention are preferably obtained from an electrodeposition bath solution comprising at least one Ni²⁺ salt and one Cu²⁺ salt, the Ni²⁺ cations being in excess with respect to the Cu²⁺ in a manner such that the reduction of Ni²⁺ is controlled by the kinetics, while the reduction of Cu²⁺ is limited by mass transfer.

Said electrodeposition bath solution may in particular comprise a Ni²⁺ salt in a concentration of 0.1 M to 0.4 M, and a Cu²⁺ salt in a concentration of 0.04 M to 0.1 M, said concentrations being adjusted in a manner such as to obtain a predetermined value for x.

The bath solution may be produced using Cu sulphate, in particular in a concentration of 0.08 M, and Ni sulphate, in particular in a concentration of 0.2 M or 0.3 M. The bath solution may also be produced using Ni sulphamate, in particular in a concentration of 0.2 M, and a Cu salt selected from the sulphate, the chloride, the citrate or the sulphamate in an appropriate concentration from 0.01 M to 0.1 M. Other Ni and Cu salts may be used without departing from the scope of the invention.

The electrodeposition bath solution preferably comprises a chelating agent for Cu²⁺ ions, in particular Na citrate in a concentration of 0.1 M to 0.2 M, and the pH of the bath solution is adjusted to a value of 6, for example by means of NaOH or H₂SO₄.

The electrodeposition bath solution preferably comprises additives selected from wetting agents, levelling agents and thickening agents, for example 1 g/L of saccharine, 2 mL/L of PC-3 and 1 mL/L of Wetting W (additives sold by A-GAS International).

As mentioned above, the process for the fabrication of a monolithic horological component in accordance with the invention is selected from UV-LiGA type processes. Said process employs a lithography substrate, which acts as a cathode during the electrodeposition step, in particular a Au/Cr/Si wafer and a photoresistant resin, for example of the SU-8 type (commercial products). The principle and the general characteristics of LiGA technology are known to the person skilled in the art and thus will not be discussed here. Only the specific characteristics intended for the production of the horological components in accordance with the invention are discussed hereinbelow.

A number of measures for improving the quality of the deposit, in particular its homogeneity, hence the homogeneity of the horological component, may be taken independently or simultaneously.

The substrate which has been printed may be exposed to an O₂ plasma before the electrodeposition step.

The electrodeposition step may employ an anode constituted by a noble metal, for example Pt, disposed parallel to and facing the cathode and, optionally, a reference electrode.

Preferably, the temperature of the electrodeposition bath solution is kept constant during the electrodeposition, in particular adjusted to 40° C., with its pH adjusted to 6.

In order to keep the composition of the bath solution constant during the electrochemical process, including in the recesses in the mold, the electrodeposition is carried out using a pulsed current, the duration of the cathodic pulses being adjusted to between 5 ms and 2 s, more particularly to between 0.3 s and 1 s, the pulses being separated by pauses with zero current in order to allow the diffusion layer at the surface of the deposit to relax. In order to reduce the duration of the deposition step, it is preferable to adjust the pauses to a duration of less than 5 s, more particularly 3 s.

In this embodiment, a current density in the range −1 mA/cm² to −200 mA/cm² is applied during the cathodic pulses. Or, in fact, a cathode potential, with respect to an Ag/AgCl electrode, in the range −0.8 V to −1.6 V is applied and maintained during the pulses.

Preferably, the electrodeposition process is initiated by a nucleation pulse with a potential adjusted to between −0.8 V and −1.6 V, with respect to an Ag/AgCl electrode, or a current density adjusted to between −1 mA/cm² and −200 mA/cm².

In particular, the nucleation pulse may be carried out at −1 V, with respect to an Ag/AgCl electrode, for 11 s. The nucleation pulse may be carried out in galvanostatic mode with a current density which is half of that for the subsequent pulses.

In addition, the bath solution is advantageously stirred during electrodeposition. Stirring may be used to increase the current density, thus leading to a faster process. In fact, the inventors have shown that in an experimental device of this type
the current density may be adjusted to approximately −390 mA/cm² per mole/L of CO in the absence of stirring,
the current density may be adjusted to approximately −830 mA/cm² per mole/L of CO with stirring at 150 rpm,
the current density may be adjusted to approximately −1.3 mA/cm² per mole/L of CO with stirring at 300 rpm,
a cathode potential of −1.3 V, with respect to an Ag/AgCl electrode, may be applied with stirring at 300 rpm.

At the end of the electrodeposition process
the latter is continued until the thickness of the deposit exceeds the thickness of the layer of resin,
the surplus thickness of the deposit with respect to the set thickness of the horological component is eliminated by polishing,
the resin is eliminated by a physico-chemical procedure, for example by means of an O₂ plasma if the resin is of the SU-8 type,
the horological component is detached from the substrate, in particular by dissolving at least the superficial layer thereof, for example with 1.5 M KOH at 80° C.

### EXAMPLES

### Example 1: Balance Spring

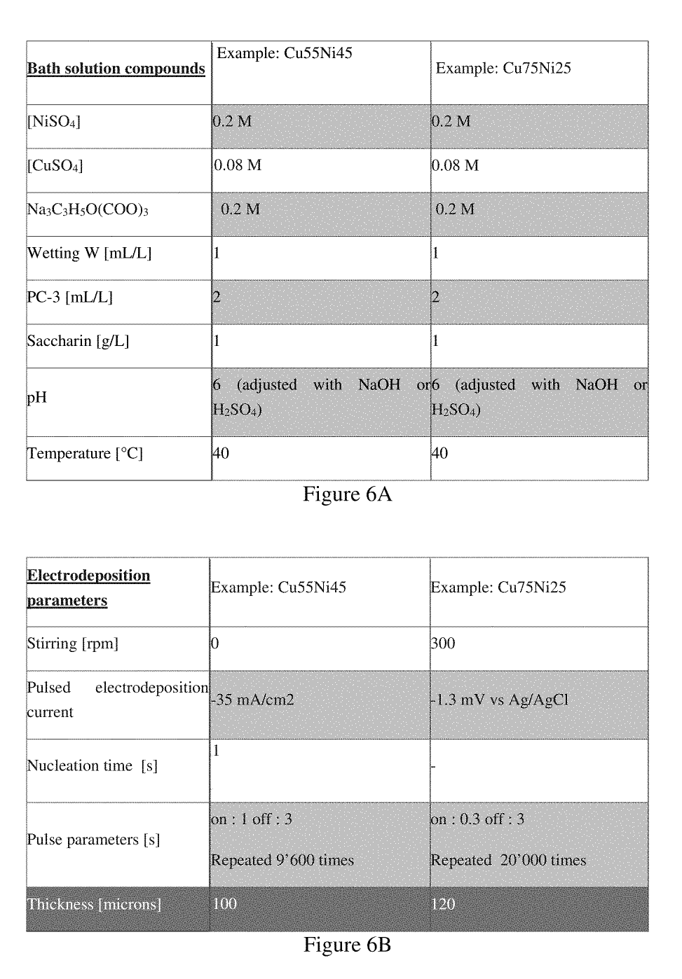

The balance spring shown in FIG. 5 was produced from a Cu(55)Ni(45) alloy using a LiGA process as described above, with the operating parameters shown in the left hand column in the table of FIG. 6.

The part obtained had the following mechanical properties:

Young's modulus: 110±10 GPa

Hardness: 2.40±0.13 GPa

Operational frequency: 2 Hz

Amplitude: 217°-268° (mean, at 6 positions).

### Example 2: Escape Wheel

The escape wheel shown in FIG. 4 was produced from a Cu(75)Ni(25) alloy using a LiGA process as described above, with the operating parameters shown in the right hand column in the table of FIG. 6.

### Example 3: Electrodeposition Bath Solutions

FIG. 6 shows the compositions of the bath solutions prepared using Ni and Cu sulphates.

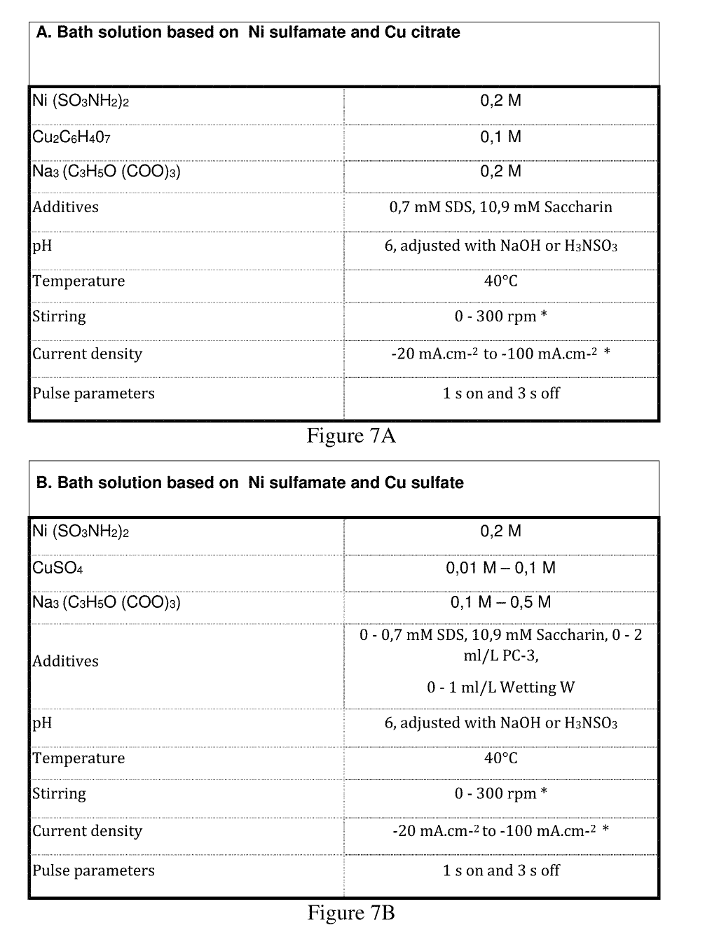

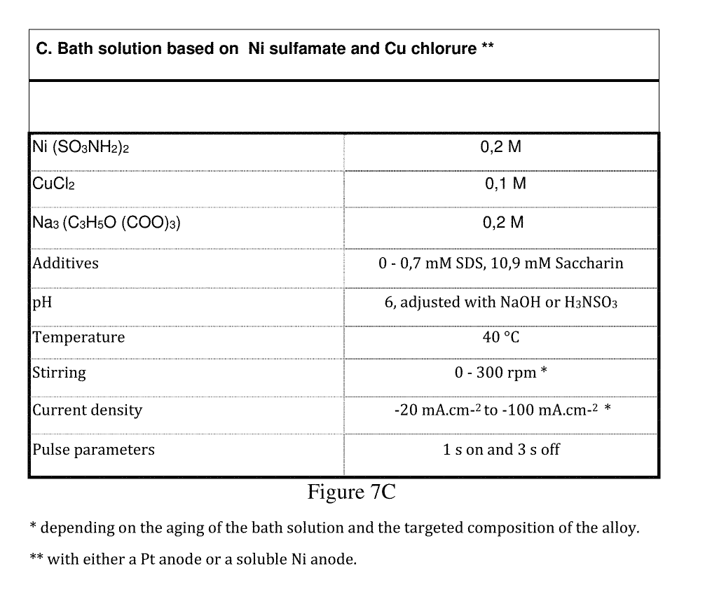

The table in FIG. 7 shows 3 examples of compositions for bath solutions prepared using Ni sulphamate and, respectively, Cu citrate, sulphate and chloride.

In view of the above discussions relating to the structure and the process for fabrication of the horological components according to the present invention, it is clear that such a horological component enjoys a number of advantages and allows to achieve the aims defined in the introduction. It should in particular be pointed out that the geometrical two-dimensional shape of such a component may be selected with almost complete freedom by the timepiece designer. The choice of the Ni and Cu components of the binary alloy, which are entirely miscible, means that there is great freedom in selecting the relative concentrations of these two species as a function of the constraints imposed on the finished product.

1. A monolithic horological component comprising an amagnetic binary CuNi alloy, said component being obtained by a process comprising the production of a mold for said component by photolithography and a step of electrodeposition.

2. The monolithic horological component according to claim 1, wherein said component is a component of a movement of a timepiece.

3. The monolithic horological component according to claim 1, wherein said component is homogeneous and isotropic.

4. The monolithic horological component according to claim 1, constituted by a binary alloy Cu(x) Ni(100-x), in which 45<x<80, where x designates the atomic percentage of copper.

5. The monolithic horological component according to claim 1, comprising a binary alloy Cu(x) Ni(100-x), in which 55<x<75, where x designates the atomic percentage of copper.

6. The monolithic horological component according to claim 1, wherein said binary CuNi alloy is obtained from an electrodeposition bath solution comprising at least one Ni²⁺ salt and one Cu²⁺ salt, the Ni²⁺ cations being in excess with respect to the Cu²⁺ in a manner such that the reduction of Ni²⁺ is controlled by kinetics, while the reduction of Cu²⁺ is limited by mass transfer.

7. The monolithic horological component according to claim 6, wherein said electrodeposition bath solution comprises a Ni²⁺ salt in a concentration of 0.1 M to 0.4 M, and a Cu²⁺ salt in a concentration of 0.04 M to 0.1 M, said concentrations being adjusted in a manner such as to obtain a predetermined value for x.

8. The monolithic horological component according to claim 6, wherein said electrodeposition bath solution additionally comprises a chelating agent for Cu²⁺ ions, in particular Na citrate, and in that a pH of the bath solution is adjusted to a value of 6.

9. The monolithic horological component according to claim 6, wherein said electrodeposition bath solution additionally comprises additives selected from wetting agents, brightening agents, levelling agents and stress-suppressing agents.

10. The monolithic horological component according to claim 1, obtained by a process selected from processes of a UV-LiGA type.

11. The monolithic horological component according to claim 10, wherein said process of the UV-LiGA type employs an Au/Cr/Si lithography substrate and a photoresistant SU-8 type resin, in that said substrate is exposed to an O₂ plasma before the electrodeposition step and in that said substrate acts as a cathode during the electrodeposition step.

12. The monolithic horological component according to claim 11, wherein the electrodeposition employs an anode comprising a noble metal, disposed parallel to and facing the cathode.

13. The monolithic horological component according to claim 12, wherein a temperature of the electrodeposition bath solution is kept constant during the electrodeposition, in particular adjusted to 40° C., and in that the bath solution is stirred during the electrodeposition.

14. The monolithic horological component according to claim 10, wherein the electrodeposition is carried out using a pulsed current, a duration of cathodic pulses being adjusted to between 5 ms and 2 s, the pulses being separated by pauses with zero current.

15. The monolithic horological component according to claim 14, wherein a current adjusted to a current density in the range −1 mA/cm² to −200 mA/cm² is applied during the cathodic pulses.

16. The monolithic horological component according to claim 14, wherein a current adjusted to a cathode potential, with respect to an Ag/AgCl electrode, in a range of −0.8V to −1.6 V is applied during the pulses.

17. The monolithic horological component according to claim 14, wherein the electrodeposition process is initiated by a nucleation pulse with a potential adjusted to between −0.8 V and −1.6 V, with respect to an Ag/AgCl electrode, or a current density adjusted to between −1 mA/cm² and −200 mA/cm².

18. The monolithic horological component according to claim 17, wherein the nucleation pulse is carried out at −1 V, and with respect to an Ag/AgCl electrode, for 11 s.

19. The monolithic horological component according to claim 17, wherein the nucleation pulse is carried out in a galvanostatic mode with a current density which is half of that for the subsequent pulses.

20. The monolithic horological component according to claim 1, comprising a binary alloy Cu(x) Ni(100-x), in which x=55, where x designates the atomic percentage of copper.
